(19) United States
(12) Patent Application Publication
(10) Pub. No.: US 2009/0038828 A1
(43) Pub. Date: Feb. 12, 2009

(54) FLEXIBLE PRINTED CIRCUIT BOARD SUBSTRATE AND FLEXIBLE PRINTED CIRCUIT BOARD FABRICATED USING THE SAME

(75) Inventors: NING HOU, Shenzhen City (CN); SHING-TZA LIOU, Tayuan (TW)

Correspondence Address: PCE INDUSTRY, INC.;ATT. CHENG-JU CHIANG, 458 E. LAMBERT ROAD, FULLERTON, CA, 92835, US

(73) Assignees: FUKUI PRECISION COMPONENT (SHENZHEN) CO., LTD., Shenzhen City (CN); FOXCONN ADVANCED TECHNOLOGY INC., Tayuan (TW)

(21) Appl. No.: 12/108,011

(22) Filed: Apr. 23, 2008

(30) Foreign Application Priority Data
Aug. 8, 2007 (CN) 200710075641.3

(51) Int. Cl. H05K 1/03; B32B 15/04

(52) U.S. Cl. 174/254; 428/457; 428/332

(57) ABSTRACT

The present invention relates to a flexible printed circuit board substrate and FPCB made from the flexible printed circuit board substrate. In one embodiment, a flexible printed circuit board substrate includes a dielectric layer, a rolled copper foil and an electroplated copper foil disposed on two opposite surfaces of the dielectric layer respectively. The contact fingers are made from electroplated copper foil, as a result, the contact fingers are stronger than that made from rolled copper foil. Furthermore, electroplated copper foils are cheaper than rolled copper foils.

### BACKGROUND

1. Technical Field

The present invention relates to flexible printed circuit board substrates and, more specifically, relates to flexible printed circuit board substrates for fabricating flexible printed circuit boards (FPCBs) and a FPCB manufactured using the same.

2. Discussion of Related Art

In recent years, with the progress of electronic and electric instrument industries, reduction in size and weight and high reliance of instruments for the communications industry, home applications and the like have been required. In order to satisfy these requirements, compact high-performance printed circuit boards are widely used in various types of electronic devices.

Flexible printed circuit boards (FPCBs) have high flexibility and can be assembled three-dimensionally, and can be adopted in various irregularly shaped electronic devices. Generally, FPCBs are made from flexible copper clad laminates (FCCLs). Typically, a flexible copper clad laminate includes a thin and flexible dielectric film and a copper foil disposed on the dielectric film. Copper foil may be rolled copper foil or electrodeposited copper foil. Generally speaking, the rolled copper foil is preferred due to its high flexibility; however, the rolled copper foil is much more expensive than the electrodeposited copper foil.

FIG. 5 illustrates a typical flexible copper clad laminate 500 including a dielectric film 50 and two rolled copper foils 51, 52 disposed on two opposite surfaces of the dielectric film 50 respectively. FIG. 6 illustrates a flexible printed circuit board 600 manufactured using the flexible copper clad laminate 500. The copper foil 51 is made into conductive traces 51a, and the copper foil 52 is made into contact fingers (edge connectors) 52a. Generally, in order to reduce transmission line widths of FPCBs, thin copper foil is preferred. However, thin copper foil, especially thin rolled copper foil is too soft, as a result, contact fingers made from thinly rolled copper foil tend to break. Furthermore, in making the contact fingers 52a, most of the copper foil 52 is etched, thus, a significant amount of copper material is consumed or wasted.

Therefore, there is a desire to develop a flexible substrate for FPCBs which is suitable for forming fine conductive traces and strong contact fingers.

### SUMMARY

In one embodiment, a flexible printed circuit board substrate includes a dielectric layer, a rolled copper foil formed on a first surface of the dielectric layer, and a electroplated copper foil formed on an opposite second surface of the dielectric layer.

This and other features and advantages of the present invention as well as the preferred embodiments thereof and flexible printed circuit board substrate and FPCB made from the flexible printed circuit board substrate in accordance with the invention will become apparent from the following detailed description and the descriptions of the drawings.

### BRIEF DESCRIPTION OF THE DRAWINGS

Many aspects of the present invention can be better understood with reference to the following drawings. The components in the drawings are not necessarily drawn to scale, the emphasis instead being placed upon clearly illustrating the principles of the present invention.

FIG. 1 illustrates a flexible printed circuit board substrate 100 in accordance with a first embodiment.

FIG. 2 illustrates a flexible printed circuit board substrate 200 in accordance with a second embodiment.

FIG. 3 illustrates a FPCB 300 made form the flexible printed circuit board substrate 100.

FIG. 4 illustrates a FPCB 400 made from the flexible printed circuit board substrate 200.

FIG. 5 illustrates a flexible printed circuit board substrate 50 in the prior art.

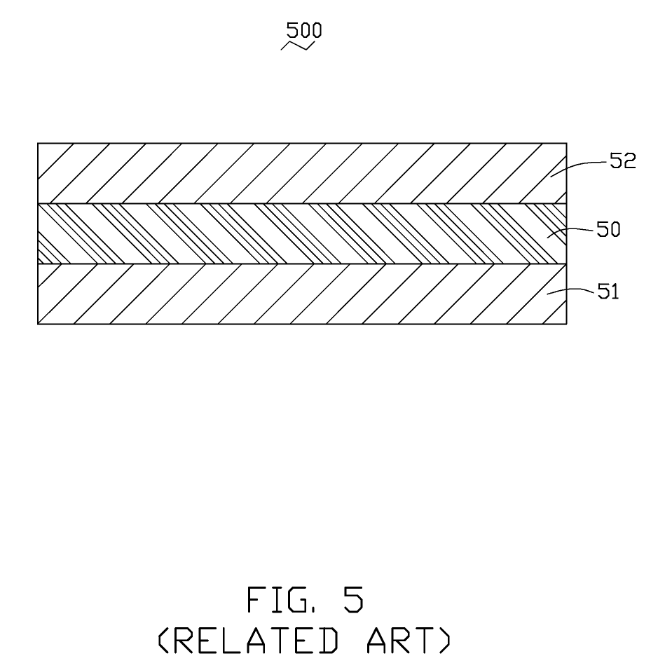

FIG. 6 illustrates a FPCB 60 made from the flexible printed circuit board substrate 50.

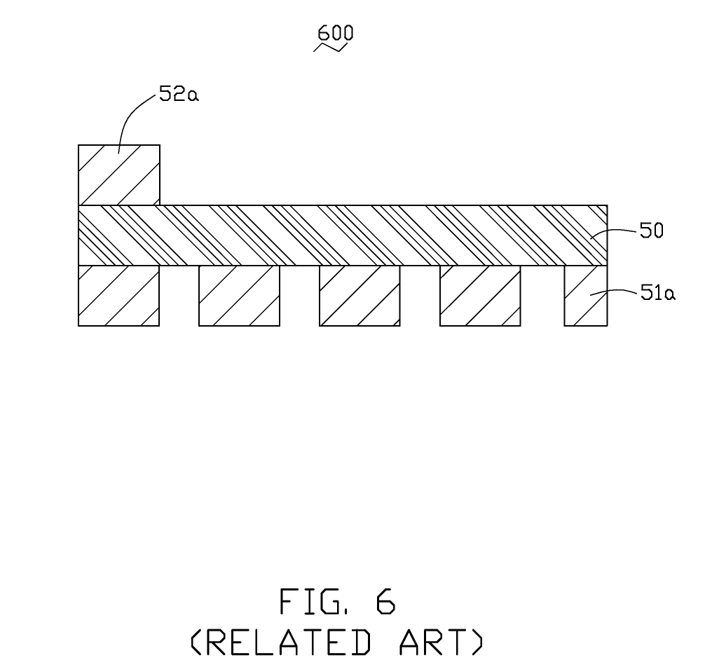

### DETAILED DESCRIPTION OF THE PREFERRED EMBODIMENTS

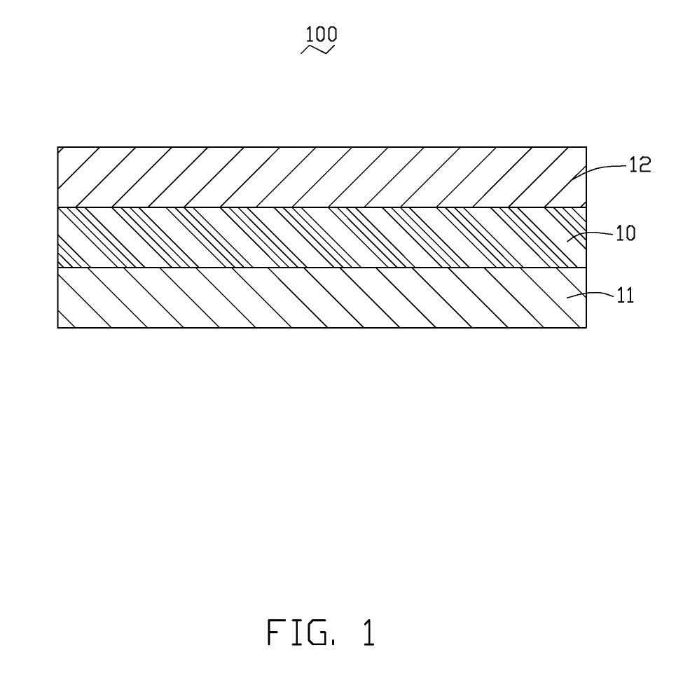

FIG. 1 illustrates a flexible printed circuit board substrate 100 in accordance with a first embodiment. The flexible printed circuit board substrate 100 includes a dielectric layer 10, a first copper foil 11 and a second copper foil 12. The dielectric layer 10 includes a first surface 101 and an opposite second surface 102. The first copper foil 11 is laminated on the first surface 101 and the second copper foil 12 is laminated on the opposite second surface 102.

The dielectric layer 10 can be made from a flexible polymer, for example, polyimide resin, epoxy resin, polyester resin, polyethylene, poly(ether-amide) resin, polytetrafluoroethylene, or liquid crystalline polymer. A thickness of the dielectric layer 10 is in a range from about 20 micrometers to about 1 millimeter. The first copper foil 11 is a rolled copper foil. The first copper foil 11 can be laminated directly on the first surface 101 of the dielectric layer 10. Preferably, the first copper foil 11 is annealed, that is, the first copper foil 11 is a rolled annealed copper foil. In order to obtain adequate flexibility, a thickness of the first copper foil 11 is in a range from about 8.5 micrometers to about 70 micrometers. The second copper foil 12 is deposited directly on the second surface 102 of the dielectric layer 10, for example, electrodeposited on the second surface 102 of the dielectric layer 10. In order to obtain adequate strength, a thickness of the second copper foil 12 is in a range from about 8.5 micrometers to about 70 micrometers. Preferably, the second copper foil 12 is thicker than the first copper foil 11.

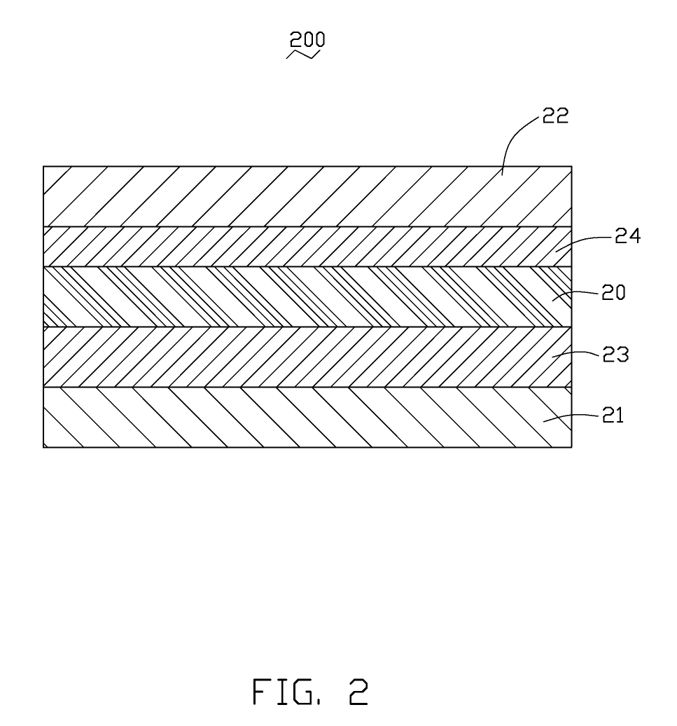

Referring to FIG. 2, a flexible printed circuit board substrate 200 in accordance with a second embodiment is similar to the flexible printed circuit board substrate 100 except that the flexible printed circuit board substrate 200 further includes a first intermediate layer 23 and a second intermediate layer 24. The first intermediate layer 23 is sandwiched between the dielectric layer 20 and the first copper foil 21. The first intermediate layers 23 can be made from polyimide, rubber, epoxy resin, fluoropolymer film such as polytetrafluoroethylene, fluorinated ethylene-propylene copolymer, and a fluorocarbon backbone with perfluoroalkoxy side chains, and crylic acid. In order to obtained adequate flexibility, a thickness of the first intermediate layer 23 can be in a range from about 8.5 micrometers to about 100 micrometers. The second intermediate layer 24 is sandwiched between the dielectric layer 20 and the second copper foil 22. The second intermediate layer 24 can be made from a metal such as nickel. The second intermediate layer 24 is configured for enhancing a bonding force between the second copper foil 22 and the dielectric layer 20. In order to obtain adequate bonding force, and avoid markedly decreasing flexibility of the flexible printed circuit board substrate 200, a thickness of the second intermediate layer 24 is in a range from about 1 micrometer to about 10 micrometers. The second intermediate layer 24 is electrodeposited on a surface of the second intermediate layer 24.

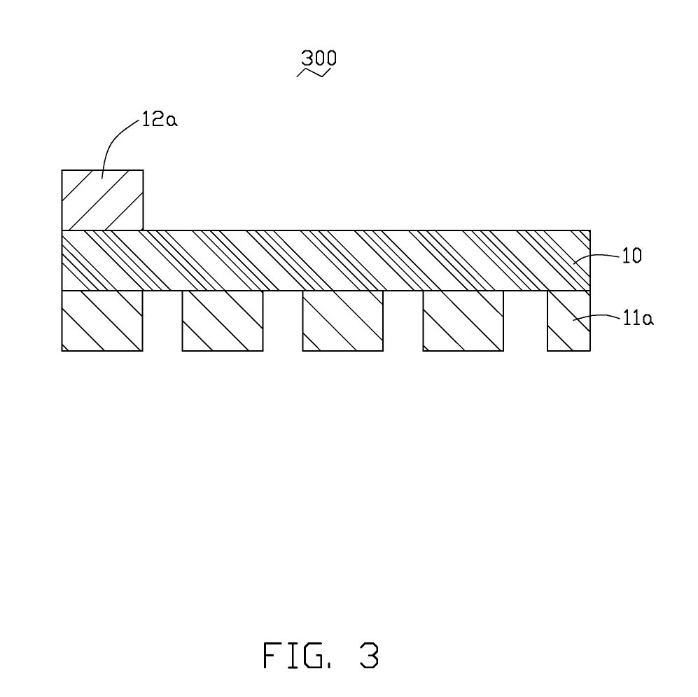

FIG. 3 illustrates a FPCB 300 made from the flexible printed circuit board substrate 100. Conductive traces 11a are made of the first copper foil 11. The contact fingers 12a are made of the second copper foil 12. The contact fingers 12 are located at or adjacent edges of the dielectric layer 10. The conductive traces 11a and the contact fingers 12a can be manufactured using an etching method or a laser ablation method. In the present embodiment, the conductive traces 11a and the contact fingers 12a are manufactured together using the etching method. In the process of forming the contact fingers 12a, most of the copper of the second copper foil 12 has been used in the etching process.

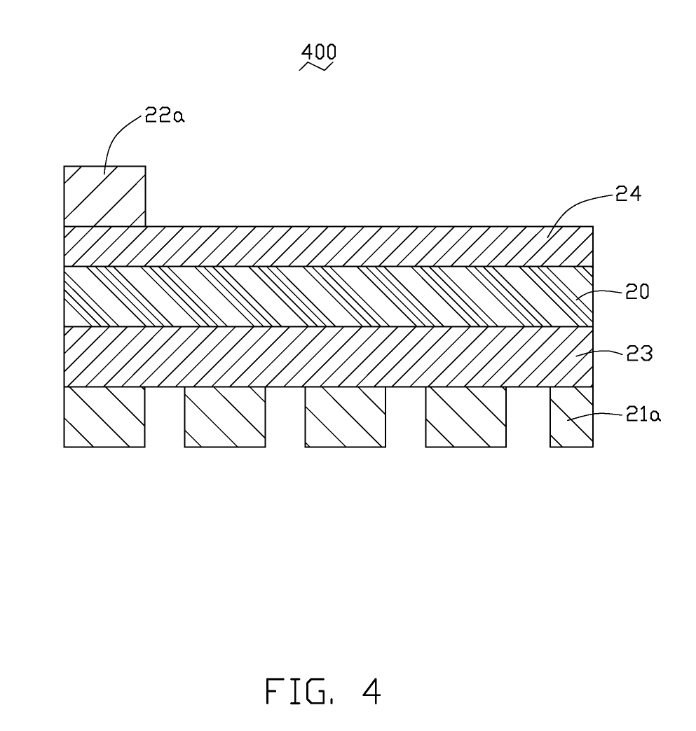

FIG. 4 illustrates an FPCB 400 made from the flexible printed circuit board substrate 200. Conductive traces 21a are made of the first copper foil 21. The contact fingers 22a are made of the second copper foil 22. Similarly, the conductive traces 21a and the contact fingers 22a are manufactured together using the etching method. In the process of forming the contact fingers 22a, most copper of the second copper foil 22 has been etched.

In the FPCBs 300, 400, the contact fingers 12a, 22a are made from deposited copper foils that have a higher rigidity than rolled copper foil, as a result, the contact fingers 12a, 22a are stronger than that made of rolled copper foils. Furthermore, deposited copper foils are cheaper than rolled copper foils; therefore the cost of etched portion of the second copper foils 12, 22 can be reduced.

Finally, it is to be understood that the above-described embodiments are intended to illustrate rather than limit the invention. Variations may be made to the embodiments without departing from the spirit of the invention as claimed. The above-described embodiments illustrate the scope of the invention but do not restrict the scope of the invention.

What is claimed is:

1. A flexible printed circuit board substrate comprising:
a dielectric layer having a first surface and an opposite second surface;
a rolled copper foil laminated on the first surface of the dielectric layer; and
an electroplated copper layer formed on the second surface of the dielectric layer using an electroplating process.

2. The flexible printed circuit board substrate as claimed in claim 1, further comprising a first intermediate layer sandwiched between the dielectric layer and the rolled copper foil.

3. The flexible printed circuit board substrate as claimed in claim 2, wherein the first intermediate layer is comprised of a material selected from the group consisting of polyimide, rubber, epoxy resin, fluoropolymer and crylic acid.

4. The flexible printed circuit board substrate as claimed in claim 2, wherein a thickness of the first intermediate layer is in a range from about 8.5 micrometers to 100 micrometers.

5. The flexible printed circuit board substrate as claimed in claim 1, further comprising a second intermediate layer sandwiched between the dielectric layer and the electroplated copper layer.

6. The flexible printed circuit board substrate as claimed in claim 5, wherein the second intermediated layer is made from nickel.

7. The flexible printed circuit board substrate as claimed in claim 5, wherein a thickness of the second intermediate layer is in a range from about 1 micrometers to about 10 micrometers.

8. The flexible printed circuit board substrate as claimed in claim 1, wherein a thickness of the dielectric layer is in a range from about 8.5 micrometers to about 70 micrometers.

9. The flexible printed circuit board substrate as claimed in claim 1, wherein the electroplated copper layer is thicker than the rolled copper foil.

10. A flexible printed circuit board, comprising:
a dielectric layer having a first surface and an opposite second surface;
a plurality of electrically conductive traces formed on the first surface of the dielectric layer, the electrically conductive traces being formed from a rolled copper foil laminated on the first surface of the dielectric layer; and
a plurality of contact fingers formed on the second surface of the dielectric layer, the contact fingers being comprised of copper electroplated on the second surface of the dielectric layer.

11. The flexible printed circuit board as claimed in claim 10, further comprising a first intermediate layer sandwiched between the dielectric layer and the conductive traces.

12. The flexible printed circuit board as claimed in claim 11, wherein the first intermediate layer is made from a material selected from the group consisting of polyimide, rubber, epoxy resin, fluoropolymer and crylic acid.

13. The flexible printed circuit board as claimed in claim 11, wherein a thickness of the first intermediate layer is in the range from 8.5 micrometers to 100 micrometers.

14. The flexible printed circuit board as claimed in claim 10, further comprising a second intermediate layer sandwiched between the dielectric layer and the contact fingers.

15. The flexible printed circuit board as claimed in claim 14, wherein the second intermediated layer is made from nickel.

16. The flexible printed circuit board as claimed in claim 14, wherein a thickness of the second intermediate layer is in the range from 1 micrometer to 10 micrometers.

17. The flexible printed circuit board as claimed in claim 10, wherein a thickness of the dielectric layer is in the range from 8.5 micrometers to 70 micrometers.

18. The flexible printed circuit board as claimed in claim 1, wherein the contact fingers are thicker than the conductive traces.
